(19) United States
(12) Patent Application Publication
(10) Pub. No.: US 2011/0082599 A1
(43) Pub. Date: Apr. 7, 2011

(54) Optimizing Utility Usage by Smart Monitoring

(76) Inventors: Makarand Shinde, Livermore, CA (US); William Brisko, San Jose, CA (US); Nitu Shinde, Livermore, CA (US)

(21) Appl. No.: 12/899,488

(22) Filed: Oct. 6, 2010

Related U.S. Application Data
(60) Provisional application No. 61/249,237, filed on Oct. 6, 2009.

(51) Int. Cl. G06F 1/28; G01R 21/00; G06F 19/00

(52) U.S. Cl. 700/295; 702/62; 702/45; 700/90

(57) ABSTRACT

A system for optimizing utility usage is described. The system comprises a monitoring device adapted to be connected to a utility point, a utility consuming device and a central processing unit (CPU). The monitoring device is configured to regulate utility usage information of the utility consuming device and is further configured to assign a unique identifier to the monitoring device. The monitoring device comprises a measurement circuit for measuring utility usage information, wherein the measurement circuit is coupled to the utility point. The monitoring device is configured to communicate with the CPU, wherein the monitoring device is configured to transmit utility usage information of the utility consuming device to the CPU on the unique identifier and wherein the monitoring device is configured to receive utility usage information of the utility consuming device and wherein the CPU is configured to process the utility usage information based on the unique identifier.

### CROSS-REFERENCE TO RELATED APPLICATIONS

This application claims priority to U.S. Provisional Application No. 61/249,237, filed Oct. 6, 2009, entitled “Optimizing Residential, Commercial and Industrial Energy Usage by Smart Monitoring and Regulation of Consumption”, which is incorporated by reference herein.

### INCORPORATION BY REFERENCE

All publications and patent applications mentioned in this specification are herein incorporated by reference to the same extent as if each individual publication or patent application was specifically and individually indicated to be incorporated by reference.

### FIELD OF THE INVENTION

This invention generally relates systems and methods for optimizing utility usage.

### BACKGROUND OF THE INVENTION

Power utility companies typically measure a customer's power consumption solely at the point at which the power enters the customer's building or unit. Measurements made at meter-level suits the needs of utility providers but not necessarily of a consumer. Improving efficiency and optimizing usage at homes and enterprises is becoming important for home and business owners who want to go “green” and save on rising energy costs without sacrificing comfort and/or productivity. Tracking and helping consumers optimize usage of utilities has conventionally been a function served by the utility providers. However, due to large customer base and volume of data, solutions provided by utility providers have traditionally relied on data collected at the meter level. Even solutions made possible by new smart grid technology for tracking electricity usage pattern are based off of real time data collected at meter level. The granularity of meter-level data is sufficient for utility providers for balancing supply-demand cycles.

Having access to meter-level data is a big improvement for consumers over the old method of receiving a monthly after-the-fact reading of usage. However, such cumulative summary of usage does not flag points and/or times of excess usage of utilities to the consumer. For the consumer, knowing the distribution of usage would be more useful than a total consumption for minimizing or eliminating waste.

If usage could be broken down to every or major points of use, solutions for optimizing would range from changing usage behavior or procedures to servicing or replacing a device or appliance consuming the utility.

### SUMMARY OF THE INVENTION

The present invention relates generally to optimizing utility usage such as electric, power, water, gas and sewage usage (henceforth referred to as “utilities”) in residential, commercial and industrial applications. In particular, one aspect of the invention concerns systems and methods for optimizing usage of utilities by smart monitoring of usage of a utility consuming device. In one embodiment, the system comprises a monitoring, measuring, or regulating device (generally referred to as a monitoring device or a SMA device) that embodies a semiconductor integrated circuit in a form factor that may be installed at every point of use of a utility in a non-invasive manner.

Another aspect of the invention is a regulation technique on a central processing unit (i.e., host computer) that assimilates utility usage information or measured data from multiple monitoring devices over a wired or wireless communication network (or a subnet). The communication network used for data transmission may be one of combination of wired/wireless Ethernet, telephone line, power line or another network. The regulation technique may be a software program in a host computer or a combination of software and hardware in a host computer.

Another aspect of the invention is that each monitoring device in a network is assigned an automatic media access control (MAC) address or identifier (i.e., digital identifier) which is used by the regulation technique for polling each device for collecting measured data. By polling every device sequentially, the software manages to streamline data collection and not cause excessive noise on the communication network whose primary function might be to carry a utility such as power, water, gas, etc.

The monitoring device may also include an embedded sensor for sensing environmental or operating parameters such as temperature, light intensity, humidity, pressure, etc. Sensed data may be transmitted along with the utility usage information or in separate data packets on the communication network. Assimilated data is used for modeling and displaying periodic (which could be real-time or near real-time) utility usage pattern, event or profile on the host computer and subsequently broadcast over the internet to a remote location or website.

Another aspect of the invention is a data collection system on the same communication network and the display of utility usage summary for various utilities such as power, water and gas individually or combination thereof on the same computer user interface. Having one interface for multiple utilities could provide residential or enterprise user a common billing interface for multiple utility providers. A two-way communication between the monitoring device and the regulation technique would facilitate implementation of optimization techniques to improve uptime of the utility consuming devices and to reduce cost by minimizing waste of utility.

Next, another aspect of the invention is a system for optimizing utility usage comprising a monitoring device adapted to be connected to a utility point and a utility consuming device. The monitoring device is configured to monitor and regulate utility usage information of the utility consuming device and is further configured to assign a unique identifier (i.e., media access control (MAC) address) to the monitoring device. The monitoring device comprises a measurement circuit for measuring utility usage information, wherein the measurement circuit is coupled to the utility point. The system also comprises a central processing unit (CPU). The monitoring device is further configured to communicate with the CPU through a communication network. The monitoring device is configured to transmit utility usage information of the utility consuming device to the CPU on the unique identifier and is also configured to receive utility usage information of the utility consuming device. The CPU is configured to process the utility usage information based on the unique identifier.

The utility point may be a power point or a flow meter. The power point may be a socket, outlet, plug, wall plate, adapter, ground fault circuit interrupter (GFCI) switch or a circuit breaker.

The utility usage information may be selected from a group including power usage information, water usage information, gas usage information and sewage usage information. The utility consuming device may be selected from a group including a power consuming device (i.e., appliance), water consuming device, gas consuming device and sewage device.

The CPU is configured to display utility usage information to a user based on the unique identifier. The CPU is configured to receive input from a user. The CPU is configured to provide a real-time or near real-time update to a user. The CPU is configured to allow a user to create an event-based profile. The event-based profile may be based on time or location. The CPU is configured to allow priority sequencing of the utility consuming device in comparison to another utility consuming device. The CPU is configured to allow a user to create a target utility consumption. The CPU comprises an application for managing utility usage information sequentially based on the unique identifier.

The communication network may comprise a wired or a wireless communication channel. The communication network may be an ethernet channel, telephone line, or power line.

The system may be configured to communicate with a ZigBee® protocol. The system may comprise a sensor connected to the monitoring device configured to vary utility usage of the utility consuming device. The sensor is configured to operate using varying current supply. The system may comprise a safety feature, a failure detection feature or a self-diagnosis feature.

The monitoring device may comprise a power profile of the utility consuming device. The power profile may comprise a range of power consumption of the utility consuming device. The power profile may comprise a disabling mode of the utility consuming device.

The monitoring device may be a semiconductor integrated chip, a multi-chip module (MCM) device, a field-programmable gate array (FPGA), or an application-specific integrated circuit device.

The monitoring device may comprise a colored LED for showing status of the utility consuming device.

The system may comprise a data collector coupled to the monitoring device and the CPU. The system may further comprise a data converter coupled to the monitoring device and the CPU. The data converter may be an analog to digital converter.

Next, another aspect of the invention is a method for optimizing utility usage. The method comprises providing a monitoring device at a utility point; coupling an utility consuming device to the monitoring device; assigning a unique identifier (i.e., media access control (MAC) address) to the monitoring device; measuring utility usage information of the utility consuming device with the monitoring device; and transmitting utility usage information from the monitoring device to a central processing unit (CPU) using the unique identifier; and processing the utility usage information at the CPU to regulate utility usage of the utility consuming device.

The method may comprise sending utility regulation information from a user to the CPU. The method may comprise creating a target utility consumption. The method may comprise priority sequencing of the utility consuming device in comparison to another utility consuming device based on the utility usage information. The method may also comprise creating an event-based profile.

The measuring step may comprise measuring an amount of current being used by the utility consuming device. The measuring step may comprise measuring voltage of the utility consuming device. The measuring step may comprise measuring pulses or digital counter from the utility consuming device.

The processing step may comprise turning off the utility consuming device or turning on the utility consuming device. The processing step may comprise controlling power to the utility consuming device or regulating amount of utility being used by the utility consuming device.

The method may further comprise communicating and displaying utility usage information to a user.

Next, another aspect of the invention is a monitoring device for optimizing utility usage information of a utility consuming device. The monitoring device comprises a microcontroller for processing utility usage information of the utility consuming device and a communication circuit coupled to the microcontroller for communicating with a central processing unit (CPU). The monitoring device also comprises a measurement circuit coupled to the microcontroller and a utility point for measuring the utility usage information. The measurement circuit comprises a current detector coupled to the microcontroller for measuring current of the utility consuming device, a voltage detector coupled to the microcontroller for measuring voltage of the utility consuming device, and a zero crossing detector coupled to the microcontroller for varying an intensity of the utility consuming device. The monitoring device also comprises a regulation circuit coupled to the microcontroller for regulating the utility usage and a sensing circuit coupled to the microcontroller for sensing environmental conditions surrounding the monitoring device.

The current detector may comprise a transformer. The zero crossing detector may comprise a comparator. The voltage detector may comprise a full wave rectifier. The monitoring device may be configured to measure half waves of alternating current waveform.

The monitoring device may comprise a Phase Locked Loop (PLL) circuit for controlling power of the utility consuming device. The monitoring device may comprise a photo transistor for measuring an amount of ambient light. The monitoring device may comprise an optical isolator for modulating power of a light source. The monitoring device may comprise a power supply of about +3.3 Volts.

The communication circuit may be an Ethernet port, telephone port or power port. The microcontroller may be configured to communicate with the communication circuit over a wired communication line.

The monitoring device may comprise a Triac (“triode for alternating current”) for controlling a utility load of the utility consuming device. The Triac may comprise a readback line to control the microcontroller.

Next, another aspect of the invention is a device for optimizing utility usage. The device is a monitoring device configured to monitor and regulate utility usage of a utility consuming device in real time. The monitoring device may have a size approximating (or alternatively no greater than) a utility point such as power point or a flow meter. The power point may be an electrical outlet plate and the monitoring device may have a size approximating (or alternatively no greater than) the electrical outlet plate. The monitoring device may have a length no greater than 4.5 inches. The monitoring device may have a width no greater than 2.75 inches.

Next, another aspect of the invention is another method for optimizing utility usage. The method comprises providing a monitoring device at a utility point; coupling a utility consuming device to the monitoring device; assigning a unique identifier to the monitoring device; polling the monitoring device using the unique identifier sequentially; upon polling of the monitoring device, transmitting utility usage information of the utility consuming device sequentially over a communication network from the monitoring device to a central processing unit (CPU); processing the utility usage information at the CPU; and monitoring and regulating utility usage of the utility consuming device. The unique identifier may be a digital identifier or a media access control (MAC) address.

The method may also comprise providing more than one monitoring device at more than one utility point; assigning a unique digital identifier to each of the monitoring devices; upon polling of more than one monitoring device, aggregating utility usage information from each of the polled monitoring devices sequentially based on each of the unique identifiers at the monitoring device; and upon polling of more than one monitoring device, transmitting utility usage information from each of the monitoring devices sequentially based on each of the unique identifiers. Each of the unique identifiers may be a digital identifier or a media access control (MAC) address.

The method may comprise coupling a sensor to the monitoring device for sensing a surrounding condition of the monitoring device and transmitting sensing information from the sensor to the CPU. The method may also comprise processing the sensing information at the CPU and providing feedback to a user or another device. The feedback may comprise preventing utility consuming device failure or regulation. The method may further comprise using a closed loop communication system for monitoring and regulating the utility consuming device.

Generally, the above methods may further comprise communicating in both directions between a monitoring device and a CPU and also in both directions between a utility consuming device and a monitoring device.

Further, the above systems and methods may be used in data center applications and township applications as provided in the description below.

Yet further, the above systems and methods provide a common platform or device for common utilities (power, water, gas and/or sewage) to be measured, regulated and monitored.

### BRIEF DESCRIPTION OF THE FIGURES

FIG. 1 illustrates one embodiment of a layout of system interfacing with a monitoring device.

FIGS. 2A, 2B and 2C illustrate various embodiments of components of the monitoring device.

FIG. 3 illustrates one embodiment of a monitoring device in form of a plug-in adaptor.

FIGS. 4A, 4B and 4C illustrate one embodiment of a monitoring device size reduction for power usage measurement.

FIGS. 5A and 5B illustrate another embodiment of a monitoring device size reduction for power usage measurement.

FIG. 6 illustrates one embodiment of a system setup for a communication over a power line.

FIG. 7 illustrates one embodiment of a system setup for communication over a telephone line.

FIG. 8 illustrates one example of a current sensing circuit for monitoring utility usage.

FIG. 9 illustrates one example of a circuit for zero crossing detection for monitoring utility usage.

FIG. 10 illustrates one example of an environmental sensor circuit for monitoring utility usage.

FIG. 11 illustrates one example of an implementation of a utility controlling mechanism in a monitoring device with an Optical Isolator/Triac circuit.

FIG. 12 illustrates an example of power supply arrangement for monitoring utility usage.

FIG. 13 illustrates one example of a voltage detecting circuit for monitoring utility usage.

### DETAILED DESCRIPTION OF INVENTION

### General Overview

One aspect of the invention further relates to a system that helps consumers or enterprises track usage of utilities at a point of use. The system preferably comprises an apparatus and a regulation technique. In particular, a system setup comprises installation of an apparatus or multiple apparatuses at points inside a facility where the utility is used. Data collected by multiple apparatuses is carried over existing connections (i.e. wiring, power, telephone or ethernet) in a facility to a CPU or a host computer and processed by the regulation technique. Data collected in this fashion from multiple points of use over time can be modeled to produce a detailed view of how, where and when utilities are used. For example, data may also be modeled to provide a real-time update to a user, allow a user to create a target utility consumption, allow a user to create an event-based profile, and further allow priority sequencing of the utility consuming device in comparison to another utility consuming device. The event-based profile may be based on time or location of a user or utility consuming device or even a mood of a user. Such granularity of data produced would allow a user to manage usage for best value.

The apparatus is henceforth referred to as Smart Monitoring Apparatus (“SMA”). The Regulation Technique (“RT) may be a computer algorithm, software program, software application or a combination of software and hardware application. The combination may be referred to as SMA+RT. Unless otherwise specified, the term “utility” or “utilities” refers to either electricity, water, gas, sewage or other utilities, or a combination of all the above. A utility zone or area is generally referred to as a utility point. The utility point may be a flow meter, a power point. In particular, the power point may be an adapter, wall plate, plug, outlet or socket. Utility usage information generally refers to data or information about the utility or utility usage. The utility usage information may specifically refer to power usage information, water usage information, gas usage information or sewage usage information. A utility consuming device may generally refer to a device or appliance that consumes a utility. The utility consuming device may specifically refer to a power consuming device, water consuming device, gas consuming device or sewage device.

By tracking power, water, gas and sewage consumption profile at every utility point (or at the most significant utility points) in a house or an enterprise, one can model usage pattern and take data driven decisions to eliminate waste, maximize utility and reduce cost of operation in the process. Utility usage pattern may be broken down to a place or point of utility use irrespective of the utility's location and provide a two-way communication to and with the point of use over a wired (power, telephone or ethernet) network or piggy-back on a network that already serves a utility function.

Data may be streamlined for communication over an existing wired network (e.g., power, voice and/or data network) such that while doing so, there is no interference to an intended function of the network. Such streamlining is achieved by reversing a mechanism for data transmission and collection. Instead of having the tracking devices, such as SMAs transmit data and wait for confirmation from the receiver, each of the SMA may be polled by the RT (i.e., software program) in a pattern which reduces overall time for data collection.

Another aspect of the invention is that the SMA+RT system reduces frequency or eliminates redundant data communication with wired networks, thus further saving data communication time. A point of distinction between wired and wireless communication modes such as the ZigBee® protocol is the amount of power needed for basic data communication. For example, communication chips used for broadcasting data on the ZigBee frequency typically consume about 12V, 150-200 mA (roughly over 2 W) or more in the process which is considered very efficient as compared to wireless ethernet. However, the same amount of data would typically require 3-5V, 150-200 mA (less than a watt). The reduced power needed for data communication in the SMA+RT system combined with the ability to eliminate redundant communication (such as send and wait for data receipt confirmations in wired modes of communication) are reasons why wired networks may be a communication backbone used for the present invention. In addition, another reason may be data integrity.

Another reason may be data integrity for use of a wired communication network. The amount of interferences that wireless devices encounter may vary over time. Devices that use a ZigBee protocol use low-powered transmitters that may further attenuate a signal to a level that the signals might not reach their receiver. A wireless phone network “blind spot” that cell-phone users commonly experience is a one example to describe a data integrity issue that wireless devices might encounter. Such blind spots are generally a result of combination of wireless noise described above and physical, natural or manmade structures that prevent wireless signals from reaching the receiver. Unlike wireless phone users, appliances have generally fixed locations and cannot be moved if to avoid wireless “blind spots”. Hence, wireless devices may or may not work in every location. In other words, wireless technology may not work in all those locations where utilities can reach. Even though both wired and wireless communication network may be utilized, wired networks may offer the data integrity that is more reliable than a wireless network.

Another aspect of the invention is to accumulate data (i.e., utility usage information) into a built-in flash memory inside the SMA until the SMA is polled by the RT. The frequency of polling versus the frequency of data collection may be controlled by a firmware program (or another program) of a microcontroller in the SMA.

Yet another aspect of the invention is to mix and match various modes of data communication between any of the wired options (i.e., power, phone, or ethernet networks). For instance, data from SMAs could be carried on power lines up to a certain point in the network and then on ethernet wires to a receiver and ultimately to a computer hosting the RT.

Another aspect of the invention is to accumulate data (i.e., utility usage information) from some or all SMAs into a modem comprising of memory for storing the data and then transmit over an internet connection to a remote computing facility. A modem may host the RT while data analysis and presentation may be performed remotely.

Another aspect of the invention is to accumulate data (i.e., utility usage information) from all SMAs into a set-top box or cable converter box consisting of memory for storing the data and then transmit over a cable to a remote computing facility. In this case, the set top box or cable converter box would host the RT and data analysis while presentation may be performed remotely.

Another aspect of the invention is to enable a service model where utility usage information that is transmitted to a remote location can be processed and the breakdown of usage summary can be presented back to a consumer at a small service fee.

Next, one embodiment of the SMA has a modular architecture that allows the SMA to be configured for measuring utilities usage information and communicating over power, phone, or ethernet lines. The communication may be done by swapping plug-in interface boards and loading appropriate firmware on a microcontroller chip. Such architecture would reduce product variations and hence manufacturing cost of the unit.

Another aspect of the invention is to configure the wired communication network as a common carrier for usage summary for any or all of the utilities—electricity, water, sewage and/or gas and keep track of various points of uses using a Media Access Control (MAC) address ID as transmitted by a microcontroller in the respective SMA.

Another aspect of the invention is a sensing circuit embedded in the SMA for sensing environmental conditions (i.e. pressure, temperature, humidity, vibration, light intensity etc.) surrounding or part of an appliance consuming the utility. The sensor data is transmitted on the communication network along with the utility usage information to a data collector.

Another aspect of the invention is to configure SMAs in various forms including but not limited to wall socket plate, a plug-in adapter, integrated with a ground circuit fault interrupt (GFCI) plug to gain a digital control on appliances including appliances that were designed and built to operate on simple ON/OFF switches. Various forms of SMAs will help consumers gain visibility and control over newer generation of smarter appliances on similar platforms.

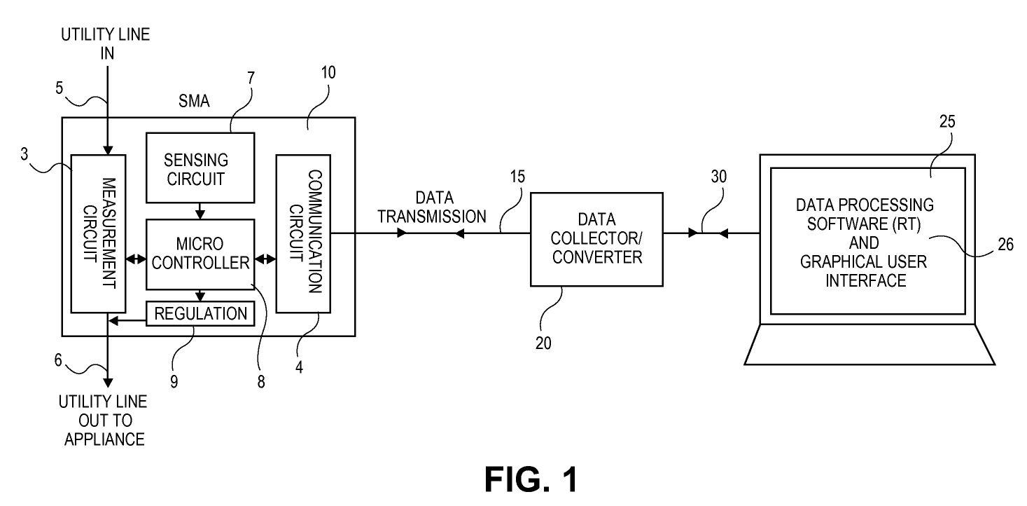

FIG. 1 illustrates a system layout of one aspect of the invention. A utility line 5 passes through a functional block of measurement circuit 3 of a SMA 10 and exits as output 6 that would go to a utility consuming device (e.g., appliance) or a network. Utility usage data is sensed by a microcontroller chip 8 and fed to a functional block for communication circuit 4. A sensing circuit 7 may sense environmental conditions such as surrounding or part of the utility consuming device that consumes the utility through the SMA output 6. The sensing circuit may have a plug-in for an external sensor. The external sensor may be used for sensing a functional parameter on one or multiple utility consuming devices in the vicinity of the SMA 10 where the utility consuming device may or may not be the one consuming the utility whose usage is monitored by the SMA 10.

Data from sensing circuit 7 along with the utility usage information from the measurement circuit 3 is accumulated and processed by microcontroller 8 and transmitted to the functional block for communication circuit 4 over a wired data transmission line 15. Alternatively, the data transmission line 15 may be wireless, in certain cases.

The functional block for regulation element 9 is an optional circuit to control the flow of the utility to the utility consuming device based on instructions from the microcontroller 8. The microcontroller 8 may generate signals for regulation based on instructions in a firmware code stored on the microcontroller or based on communication from the RT host computer. Transmission lines such as 15 from various SMAs will channel data to a data collector 20 which in turn transmits data over wired or wireless communication channel 30 to a computer 25 that hosts the data processing software or graphical user interface (RT) 26. Alternatively, the system layout of FIG. 1 may not include a sensing circuit. Another alternative could be that the system layout of FIG. 1 may not include a regulation circuit.

Another aspect of this invention is to configure the SMA system to be non-invasive, encompassing space and accessibility requirements for points where a utility is used. For example, to track electricity consumed by an appliance that is plugged into a standard US 2-outlet, AC wall socket or another non-invasive method, the SMA is provided in form of a plug-in adapter that may go in between the socket and the appliance plug and carry data via a power line to a computer plugged into a wall socket at another location in the same electric network. If the appliance shares the wall socket with another appliance, the SMA is configured in form of an adaptor to be non-invasive, without blocking the neighboring outlet, if desired. The SMA devices provide a least disruptive installation or setup process and a modular approach for ease of serviceability.

Another example is a SMA system setup where there is a flow meter with a digital display installed to track usage of water and an electric solenoid valve to regulate supply. The set-up may offer a non-invasive way for real time tracking without the need to replace an existing meter or valve and with very little setup change. In this setup, the SMA may tap into a signal fed to a digital display in case of a digital flow meter or tap into a pulse generated by a analog flow meter for monitoring usage data and plug into a nearby electric outlet to send data through the power line (or another communication network). The data can be collected into a computer or other device at another socket in a same electric network. In addition, signals from the remote computer could be fed to the electric solenoid valve processed via a regulation circuit in the SMA. In the setup, a static or remote utility point of use may be converted to a dynamic, real-time, closed-loop system with minimal disruption to the existing setup. Alternatively, the usage data from flow meters may be routed via a combination of wired/wireless networks. This set-up is also applicable to gas flow meters monitoring and regulation.

Further, the size of an SMA is a function of the combination of ICs for a desired functionality. One aspect of this invention is to optimize design and consolidation of circuits for each function to reduce a package size of the SMA.

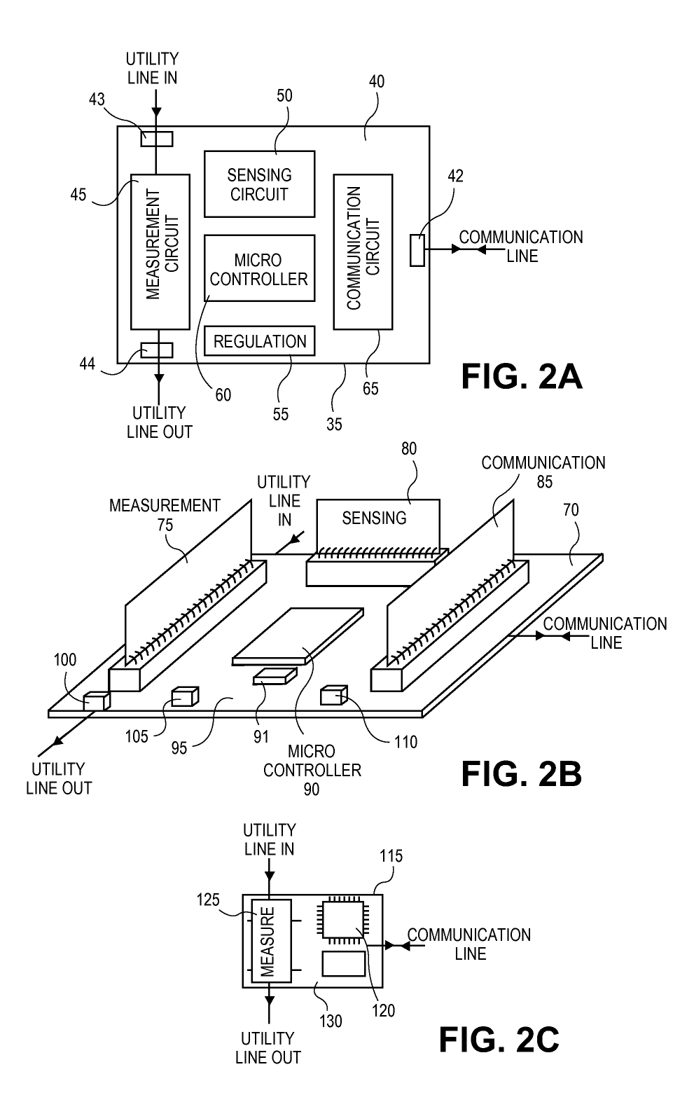

FIG. 2 illustrates various embodiments of a SMA chip-set in unpackaged form. The chipset may be packaged before marketing. Also, the illustrations shown may or may not be to scale. The SMA may be a combination of several integrated circuits (ICs) that accomplish various functions. The SMA may be a multi-chip module (MCM) with multiple ICs mounted on a base substrate that is made of either a printed circuit board (PCB) or ceramic. Alternatively, bare silicon die may be used for ICs that make up various functional blocks inside the SMA to reduce the SMA package size. The SMA may also be an application-specific integrated circuit device or a field-programmable gate array (FPGA).

The SMA may be in a form factor for non-invasive installation and have a modular design to minimize production and service costs. Also, the SMA may be in form factor that does not interfere with surrounding infrastructure and devices. The SMA may have a size approximating the utility point (or alternatively be no greater than the size of the utility point) such as a power point. As an example, the SMA may have a size no greater than an electrical wall plate. The SMA may have a length no greater than 4.5 inches or a width no greater than 2.75 inches. Specifically, the SMA may have a length approximately of 3.5 inches or a width approximately of 2.0 inches. As illustrated in FIG. 2, SMA 40 may match a size of a footprint (e.g. 1.5″ long, 2.5″ wide and 1.5″ high) of a socket in a standard US 2-outlet 110V, AC wall socket plate. The SMA may approximate (or alternatively be no greater than) the size of other sockets, outlets, plugs, adapters, ground fault circuit interrupter (GFCI) switches, circuit breakers, or any other devices. Unless otherwise preferred, such an SMA will not block access to an adjacent socket.

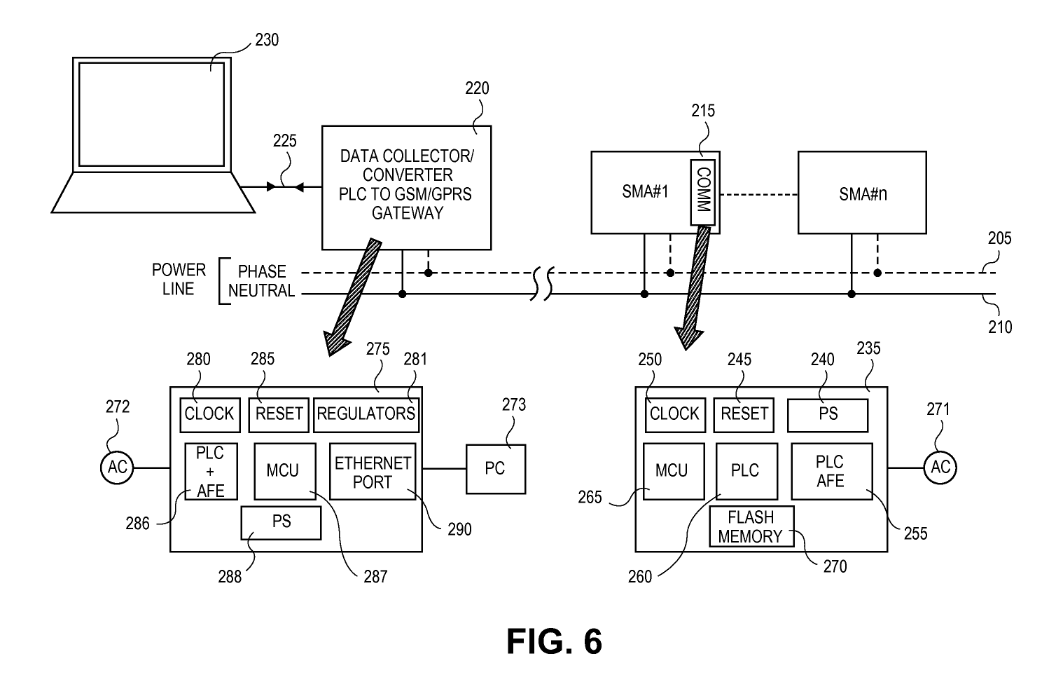

FIG. 2 further illustrates various evolutionary phases of the SMA. With every phase, the intent is to reduce the size of the SMA chipset. In FIG. 2A, SMA 40 is a chipset where all the ICs are mounted directly on a base printed circuit board (PCB) 35. PCB 35 has the necessary circuitry that connects each of the functional blocks 45 for utility measurement. FIG. 2A illustrates sensing circuit 50 for sensing, communication circuit 65 for communication and regulation element 55. The SMA 40 comprises a microcontroller IC 60 which coordinates communication to and between each of the functional blocks in FIG. 6. In addition, there are standard sockets 43 for utility line plug-in and utility line out 44 along with a socket 42 for plugging in communication line to send data collected into a wired network.

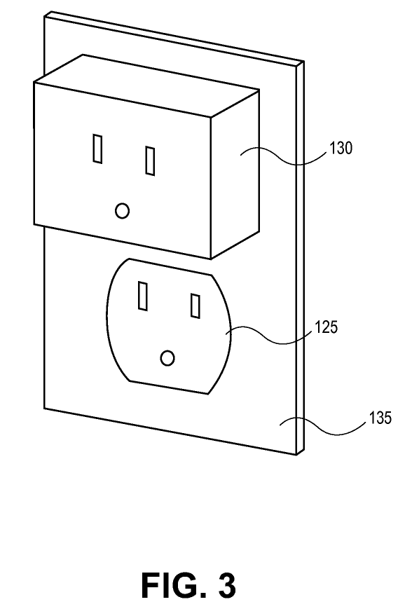

An aspect of this invention is an electricity usage monitoring device as described in the above paragraphs and as shown in FIG. 3. In FIG. 3, the SMA 130 is in form of a plug-in adaptor. As an example, the SMA 130 may be installed on a standard US, 2-outlet, 110V AC wall socket plate 135 without blocking access to the adjacent socket 125 for a standard US 110V AC plug.

In FIG. 2B, SMA 70 is a modular version of SMA 40. The SMA 70 has each functional block implemented in form of interface cards 75, 80 and 85. This architecture allows flexibility in configuration so the same SMA board 95 could be used for measuring electricity, water, sewage or gas (or another utility) by a swap of the measurement card 75 and may further communicate via a communication line (i.e. power, phone, or ethernet lines) by switching to the appropriate communication board 85. The SMA 70 may be configured to sense various environmental conditions by plugging the appropriate sensing card 80. The SMA may also have standard connectors for external interface to each of the interface boards. An interface 100 is provided for an external utility line. FIG. 2B also show element 105 for an external sensor input and element 110 for external communication line. The microcontroller 90 and the regulation circuit 91 may be common features in an SMA. Additionally, SMA 70 may resemble a standard internet modem (e.g. 4″ wide, 4″ long and 1.5″ high modem).

In FIG. 2C, SMA 115 is a representation showing a reduction in size of the SMA. The reduction in size occurs by combining circuitry and capabilities of a microcontroller and circuitry of functional blocks for communication, sense, regulation, and further implementing it on an integrated circuit (IC) 120. Implementing circuitry in the IC may eliminate the need for special ICs for separate functional blocks. The measurement circuit 125 may be reduced in size by using a ceramic chipset with ICs in form of silicon. A silicon die can be attached on a PCB or ceramic substrate by chip-set manufacturers. As an example, SMA 115 is configured to fit inside the area defined by 3 prongs of a standard US 110V AC plug. Alternatively, SMA 115 may be configured to fit in socket, plug, outlet, wall plate, adapter or another device.

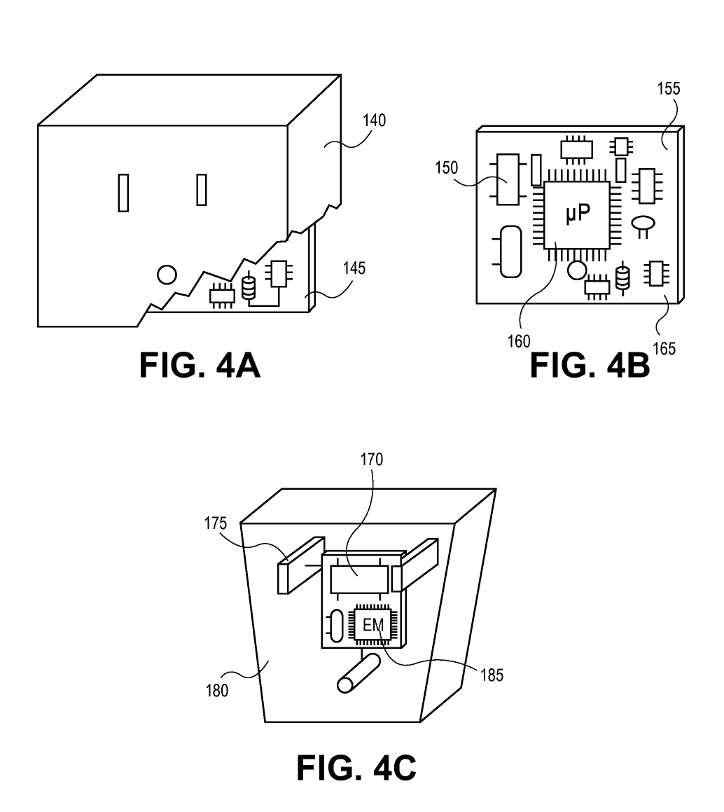

Next, FIG. 4 illustrates SMA size reduction for electricity measurement. SMA 145 illustrated in FIG. 4B may be built into plug-in adaptor 140 as in SMA 155 illustrated in FIG. 4A. SMA 145 may be a combination of various ICs such as 150 for measurement and microcontroller 160 mounted on a PCB 165. Alternatively, a smaller SMA 185 may enable an even smaller footprint for adaptor 180 illustrated in FIG. 4C. Such a small footprint could be achieved by consolidating discrete ICs performing one or multiple functions such as communication, regulation, sensing into a custom IC 185 to reduce the overall SMA size so it can reside inside the volume defined by contacts 175 of a standard electric plug. IC 170 could be used for measurement.

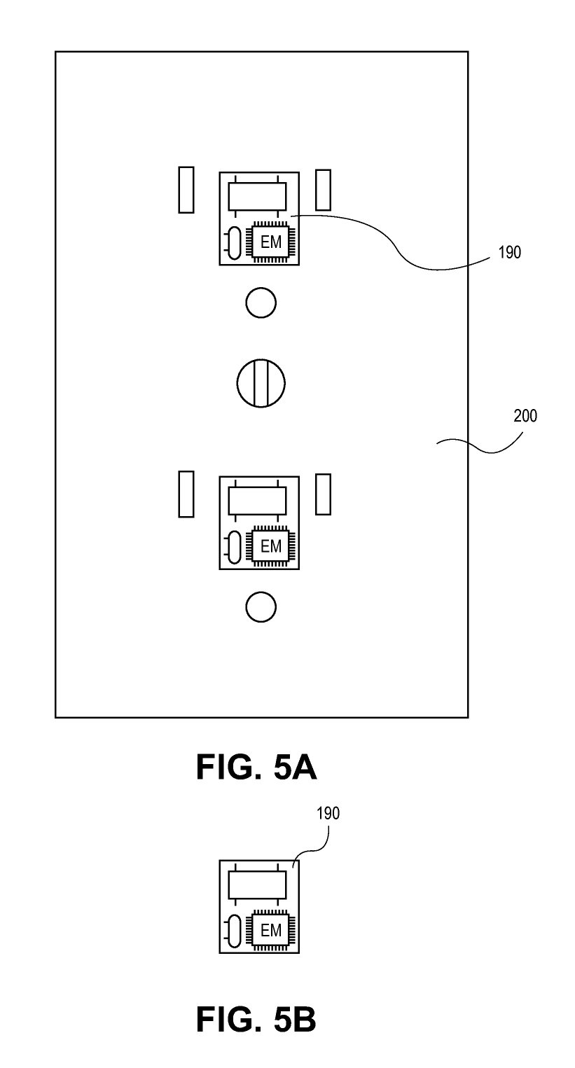

FIG. 5 illustrates yet another variation of a small sized SMA 190 that can be nestled into a standard socket (i.e. US 110V AC 2-outlet socket unit). The embedded firmware on the SMA could be modified to support the IEEE802.15.4, ZigBee protocol, or another protocol to enable communication to a network of wireless SMA(s) interconnected to the wired SMA network through a switch to form a wired-wireless hybrid monitoring scheme.

### Design Overview

In general, the SMA has built-in intelligence. The intelligence may be the in form of either a programmable interface controller (PIC) microcontroller or stripped down Advanced RISC Machine (ARM) core. The microcontroller is capable of measuring analog voltages for electricity measurement, or is further capable of reading pulses or digital counters from water or gas flow meters. Water and gas usage measurements are typically based on volume of water or gas flowing through a flow meter. Electric power has two components to it—voltage and current. Monitoring power usage is based on how much current is being used by the power consuming device at any moment since utility providers supply power to the end user at a voltage that is constant within a certain range. The variable in the US is the current usage (and more subtly, phase angle). There are possibly three methods to measure current directly in an AC path: One method is to measure the voltage drop over a resistor. Another method is to measure current with mutual inductance (essentially, a transformer.) The last method is to use a Hall-effect sensor.

Measuring a voltage drop across a resistor may generate around 10 Watts of power, which would have to be dissipated in the SMA or in the wiring itself (i.e. house wiring).

Measuring current with mutual inductance comprises the following methodology because alternating current (AC) is time-varying. A time varying current may generate a magnetic field and, therefore, can generate a voltage. If a wire is passed through a toroid and a small coil wound on the same toroid, a voltage in the secondary winding proportional to the measured current is generated. A core capable of about 30 Amps may be about ⅝″ in diameter. When this winding is terminated with a large value resistor (about 5K Ohms), a voltage across the resistor proportional to the current used is generated. This voltage is measured using a PIC analog-to-digital converter. The peak-to-peak values of voltage are converted to root-mean-squared (RMS) values. The data packet, at regular intervals, is sent along to the communication functional block in the SMA.

Next, a Hall-effect sensor could be used to measure the magnetic field. Mall-effect sensors can be used to measure DC magnetic fields, where Hall-effect directly measures static field in the toroid.

In addition to utility measurement circuitry, the SMA comprises a triode for alternating current or Triac (or relay) to control current supply to the utility consuming device that can tolerate varying current supply such as an incandescent bulb. The Triac is a semiconductor device that can control current with a small voltage applied to a control pin.

Another aspect of this invention comprises using the current transformer, the microcontroller, and the Triac (or relay) to control and manipulate and regulate utility consuming devices or other device/network loads. The control, manipulation & regulation may be done via an application while measuring current usage, using a software program as a RT. The program may be used to determine if the usage is appropriate and to control a utility load with the Triac (or relay) locally at the SMA. The SMA can monitor how much current is passing through each wall socket and turn off or regulate sockets to keep usage below baseline rates.

Yet another aspect of the invention is to use SMAs for charging electric cars or regulating electric car function. The SMA is configured to operate on a standard voltage of 120V (up to 20 A current) which is also equivalent to what is termed as a Level I charging level for PHEVs (Plug-in Hybrid Electric Vehicle). The SMA architecture is also scalable to serve Level II (voltage of 240V, up to 40 A current) and Level III (voltage of 480V up to 40 A current). Safety features in the SMAs have been configured to scale up and be able to upgrade to meet the safety standards as published by the National Electric Manufacturers Association, the Society of Automotive Engineers, and other standards.

### Detailed Design Description

One embodiment configured to monitor and regulate utility usage may comprise using a transformer. In this method, the transformer may comprise coil of wire on a ferrite core. A hot lead (black wire) from an AC line is passed through the core and a voltage will appear on the leads of the core proportional to the current in the AC lead.

Another embodiment configured to monitor and regulate utility usage comprises using an analog to digital convertor (A2D). The converter may be single-ended (i.e. input doesn't allow positive AND negative waveforms) and its range may be 3.3 Volts. One aspect of the invention is to maintain utility usage measurement accuracy and integrity. As such, the output of the transformer may be rectified as with a power supply. The negative end of a bridge rectifier is tied to ground and all waveforms become positive. Accordingly, the positive, single-ended waveforms are measured, and an entire 3.3 Volt range may be used instead of half the range.

For SMAs used for monitoring electricity usage, an output of the transformer, may be terminated with a resistor to generate a voltage to measure. The resistance of the resistor may be higher than the impedance of the coil (i.e., about 20 KOhm resistance for a 5 KOhm coil impedance) such that the terminating resistor does not act like a divider. Maximum voltage across a resistance may be produced. For small currents, a voltage to sample in the 1-3 Volt range is produced. However, for larger currents on the AC line, the coil will begin to produce non-linear voltages.

For SMAs used for monitoring electricity usage, in order to measure currents over 5 A, two more resistors may be included that shunt the original terminating resistance. The purpose of these resistors is that the resistors are grounded by the microcontroller when the A2D detects operation near the top of its range. The first shunt is grounded, changing the terminating resistance, and making the detector less sensitive (for greater AC line currents.) For the large loads in excess of 20 A, a second resistor may be used as a shunt to make the terminating resistance even less. This gives a range of sensitivities to measure and does not tax the A2D, which may be only 10-bits, at the lower end of its range.

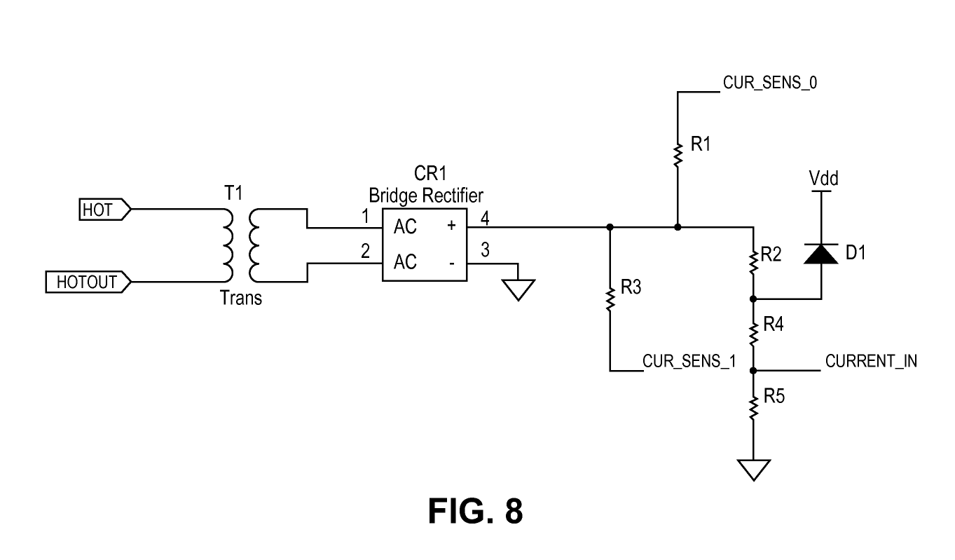

FIG. 8 illustrates one example of a current detecting circuit arrangement for an SMA used for monitoring electricity usage described in sections above. T1 is the current transformer which may have a high turn ratio of 1000:1. Once passing through the transformer, a current waveform is rectified by a bridge CR1. The most sensitive range is set by resistors R2, R4 and R5, which total to 20 KOhm. A diode attached to Vdd on a first leg of the divider to protect the A2D (not shown in FIG. 8) in case of voltage spikes. The A2D measures voltages on a second leg of the divider. For sensing small currents on a power line up to about 5 Amps, the detector may generate about 20 Volts, whereby voltage drop across a bridge rectifier CR1 may be ignored. Resistors R1 and R3 are the first and second shunts described in the paragraphs above. R1 and R3 are selected by the microcontroller in case current through current transformer T1 exceeds 5A and 20A respectively when the voltage response becomes non-linear.

Next, a zero Crossing Detector for an SMA may be used for monitoring electricity usage. Zero crossings are where the AC waveforms cross 0 Volts. If a Triac (or relay) is being used as a chopper circuit, as in a light dimmer turning ON the Triac (or relay) is delayed for a set time after a zero crossing. When Triac (or relay) is turned on, the Triac (or relay) will conduct until the next zero crossing. In this way, an intensity of the light bulb can be controlled. Also, if the Triac (or relay) is used as a switch to turn a motor or television ON and OFF, the Triac (or relay) may not be overloaded by the power supply being switched by turning the Triac (or relay) ON and OFF at the zero crossings. The sampling of the AC waveform for voltage and current measurement will be timed off the zero crossings. This will help to achieve high measurement accuracy of power measurement.

In the US, the National Broadcasting society (NBS) specification is from 47.5 Hertz to 61.5 Hertz. For SMAs used for monitoring electricity usage, the best way to measure the power, in such a wide range of transmission frequency, is to trigger off of the zero crossing and take 128 samples timed across the positive and negative crests of the cycle. Two zero crossings may be experienced in that time—when the waveform goes positive and one when it goes negative. To get an accurate measurement of samples at a next zero crossing, loss associated with frequency deviation may be quantified and adjustments to the values measured may be made to compensate for loss of data. Also, to get an accurate measurement, setting an internal timer for the samples to match a period of the previous wave and base measurements on the timer may be done.

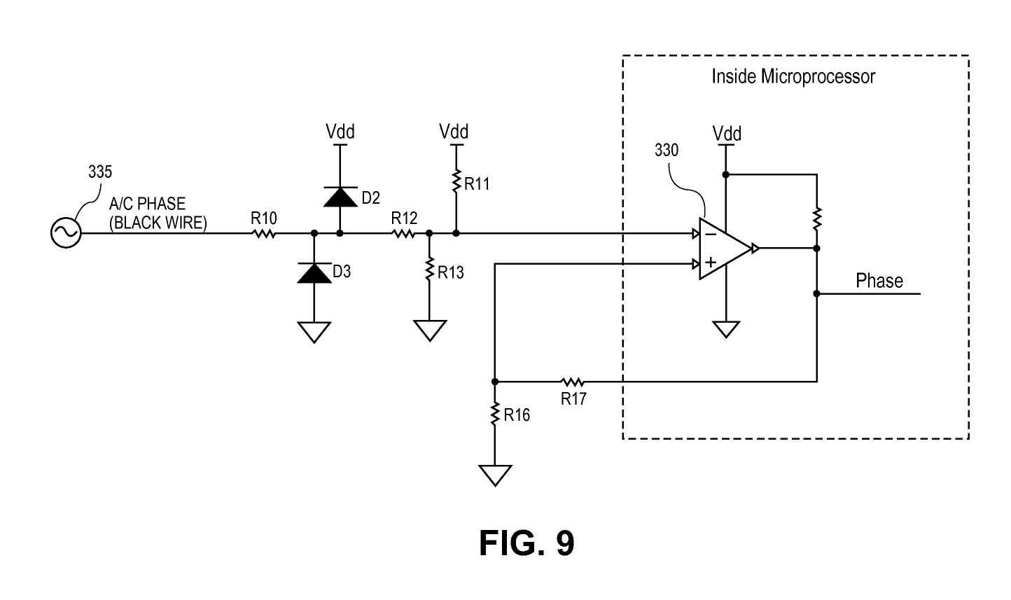

FIG. 9 illustrates one example of a circuit for zero crossing detection and associated protection circuit for the microcontroller inside an SMA used for monitoring electricity usage. In FIG. 9, an input AC waveform 335 goes to a comparator, 330 which is internal to the microcontroller. A comparator is a circuit that detects each time an AC pulse changes polarity. The output of the comparator changes state each time the pulse changes its polarity; that is, the output is HI (high) for a positive pulse and LO (low) for a negative pulse. The comparator 330 is used for zero crossing detection. The comparator also amplifies and squares the input signal. This comparator squares up a signal waveform so there is no jitter associated with the zero crossings.

In FIG. 9, Resistors R16 and R17 are designed to form a positive feedback loop for the comparator providing a little hysteresis to further eliminate the jitter. For protecting the microcontroller, an AC current is passed through a high value resistor R10 in the order of 500 ohms. Being sensitive, R10 acts as a fuse and prevents high currents from reaching and potentially damaging the microcontroller from transient currents on the power line. Transient currents, also known as inrush currents, are an instantaneous high current seen when an electric circuit is turned on. Inrush current in AC circuits (especially for motors) are sometimes in multiples of the maximum current rating of the utility consuming device. The microcontroller in the SMA needs protection from such high currents and resistor R10 serves this purpose.

In FIG. 9, diodes D2 and D3 clamp the signal waveform between Vdd and ground to protect the microcontroller from excess voltages on the input pin. Resistive dividers R12/R13 further protect the microcontroller. Preferably, the microcontroller should not see any voltages more or less than a diode-drop from either Vdd or ground. But the voltage at the diodes D2 and D3 may be a diode-drop from either Vdd or ground. This could produce a phenomenon known as latch-up. Latch-up is a term used in the realm of integrated circuits (ICs) to describe a particular type of short circuit which can occur in an improperly designed circuit. Such a short could disrupt proper functioning of the IC and possibly cause damage due to over current. A power cycle is typically required to correct this situation. If a latch-up were to occur in the SMA circuit, it may occur in the circuit arrangement illustrated in FIG. 9. As such, a divider halves the voltage at diodes D2, D3 further down to half a diode-drop, which may prevent latch-up.

Further, Resistor R11 sets a small bias current. The current signal is sent to a comparator which is an internal part of the microcontroller IC. The protection circuit including an input capacity of the comparator, an input pin to the microcontroller itself (about 15 pF capacitance, and about 500 nA leakage), R11 and the R16/R17 feedback loop may affect the exact zero crossing point.

Another aspect of this invention is to a Phase Locked Loop (PLL) circuit and use the PLL circuit for power monitoring and regulating the utilities. Phase Locked Loop may be included in a SMA. An alternative to a self-clocking circuit may be to have a clock circuit driven by a crystal and implement a PLL circuit around it. A PLL circuit is a control system that generates an output signal whose phase is related to the phase of an input “reference” signal. A PLL circuit seeks in only one direction, not both. Such a circuit would lock with 50 Hz in Europe and Asia, and also to 60 Hz in the US and elsewhere.

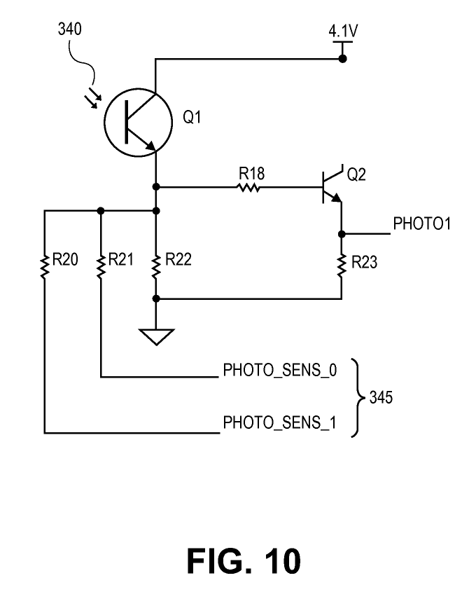

FIG. 10 illustrates an example of an SMA with an environmental sensor for managing utility usage. The example depicted in FIG. 10 is specifically of a light sensor in form of a photo transistor that may be used for lighting regulation using an SMA. FIG. 10 particularly provides an example of how an output of an SMA can be used to control lighting to a constant intensity using a photo sensor. The SMA are designed to interact with other types of sensors such as heat, temperature, pressure or humidity sensors to provide similar regulation for relevant utility consuming devices.

A circuit that may be used on the lighting socket, but not necessarily in the wall socket, is the photo transistor. Such a circuit measures the amount of ambient light in order to modulate lamps ON, OFF or in the middle of a lighting arrangement in the case of daylight. The circuit may be used to open mini shades or regulate other appliances. The photo transistor circuit is similar to the current detector in that it needs to have a dynamic range for example a 10-bit A2D. Ambient light in a living room at night may be 400 Lux. A dark room that one can still see in may be below 100 Lux. Subdued daylight can be about 30,000 Lux and direct sunlight may be on the order of 100,000-300,000 Lux. Since there is a 10-bit A2D, slicing 300,000 Lux into enough slices to make a difference (each bit would represent about 300 Lux) may or may not be done. On the other hand, if we set the photo transistor circuit for fine operation in a dark room, the lighting would saturate in a room of 1024 Lux, which is a room with the shades open in daylight.

In particular, FIG. 10 illustrates an embodiment of a photo transistor into a SMA circuit. The circuit topology may be a Darlington pair for carrying a linear response from photo transistor Q1 through to transistor Q2 and then to the A2D. A Darlington pair is a compound structure comprising of two bipolar transistors (either integrated or separated devices) connected in such a way that the current amplified by the first transistor is amplified further by the second one. The paired configuration of photo transistors gives a much higher current gain than each transistor taken separately.

It may not be possible to get a response from transistor Q2 near ground, since Q2 may stop conducting with decreasing ambient light 340 on Q1. Response from Q2 could be achieved by setting one of the breakpoints to switch in the other emitter resistors (R20 and R21) when the emitter of Q2 reaches about 0.7 Volts.

Moreover, collector-emitter saturation voltage in Q1 is 0.1 Volts when fully saturated. With a drop in R18 and the base-emitter drop in Q2, the highest voltage the emitter of Q2 may go is (0.7V+0.1V=0.8V) Vdd−0.8V which needs to make it to Vdd (though breakpoint can be set to switch Q1's emitter resistors at about Vdd−0.7V). A low-current power supply with a Zener for 4.1 Volts may be added. As a result, the emitter of Q2 would drive to the value of Vdd (4.1V−0.8V=3.3V) which may result in a usable input range of 3.3 Volts (all 1024-bits) with a non-linear section at 0.7 Volts and below the non-linear section at Vdd−0.7V which in turn would be points where breakpoints are set in the A2D readings to switch out the additional emitter resistors for Q1 (R20 and R21) to change sensitivity. Q2 is a high-gain transistor (minimum hFE of 500) so that the base-emitter current of Q2 is lower than the emitter current of Q1 (by a wide margin) which minimizes the effects a drive current for Q2 has on the linearity of Q1.

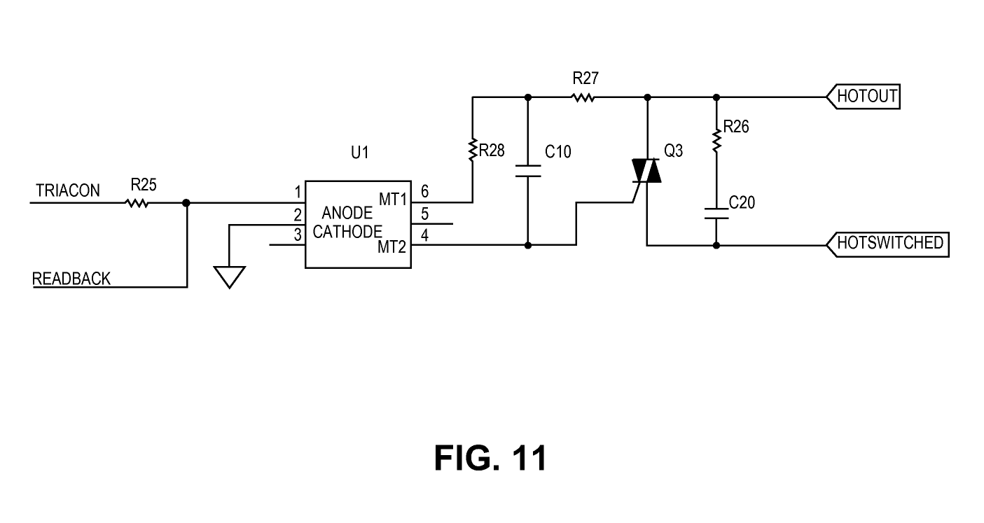

Next, FIG. 11 illustrates an implementation of a utility usage controlling mechanism in the SMA with an Optical Isolator or Triac (or relay) circuit. The arrangement in FIG. 10 is an example in the SMA for monitoring electricity usage and for modulating power to utility consuming devices for varying current supply such as in an incandescent bulb and further to use the SMA as remote controlled ON and OFF switches. A Triac is a shortform used for Triode for Alternating Current. U1 is a solid-state device (bi-polar technology) that acts like a relay. When a voltage is applied on a gate, terminals MT1 and MT2 will conduct until the current through MT1/MT2 stops, which is what happens when the AC waveform goes through a zero crossing. The Triac (or relay) operation is divided into quadrants based on the polarity of the AC voltage and the Gate voltage.

One aspect of the invention will operate the Triac (or relay) in what is known as quadrant 1 and 3. This is done by energizing the Triac (or relay) with an optical isolating device. The SMA device: 1) allows the Triac (or relay) ON in quadrant 1 and 3 to be turned ON because the optical isolator is bi-polar and 2) isolates the Triac (or relay) from the microcontroller. If the Triac (or relay) fails, the microcontroller may be exposed to 120 Volts RMS, which may damage the microcontroller. If a spurious noise comes through a gate pin, it could cause the microcontroller to latch-up through some path to ground. In this way, the socket could be repaired simply by replacing the Triac (or relay) or the optical isolator. The signal to turn on the Triac (or relay) is provided from the microcontroller via net TRIAC (OR RELAY)_ON. The Triac (or relay) goes through resistor R25 and through an LED internal to U1. The LED shines onto a set of phototransistors on the other side of U1 and shorts the lines MT 1 and MT2 on U1. This pulls a gate of transistor Q3, the Triac (or relay), up to the potential of its MT1 terminal (a hot side of the AC line) and the Triac (or relay) turns ON. The Triac (or relay) will continue to conduct until the current through its MT1/MT2 terminals stops.

In FIG. 11, capacitor C10 may be used to slow down turn-on voltage to a gate and suppress some noise. R2 and C20 are to suppress RF noise in case the Triac (or relay) turns on at highest point in the AC wave.

One aspect of the invention is a line on a net between R2 and U1 labeled READBACK. This is a read back line for the microcontroller to verify that U1 has turned ON. A voltage on that line when TRIAC (OR RELAY)_ON is off will be 0 Volts. The READBACK line then can verify it is 0 Volts. When the Triac (or relay) is turned ON, the line (TRIAC (OR RELAY)_ON) will go to Vdd, which is 3.3 Volts. The LED internal to U1 will drop about 0.7 Volts, so line READBACK will read a logic low. However, if the LED is bad (or open) the, line READBACK will be 3.3 Volts. There is the possibility that the LED in U1 is shorted, in which case the READBACK will still read low and the Triac (or relay) will not trigger. For verification, there is a voltage detector circuit on the output of the Triac (or relay) which will signal the microcontroller that the Triac (or relay) is either ON or OFF.

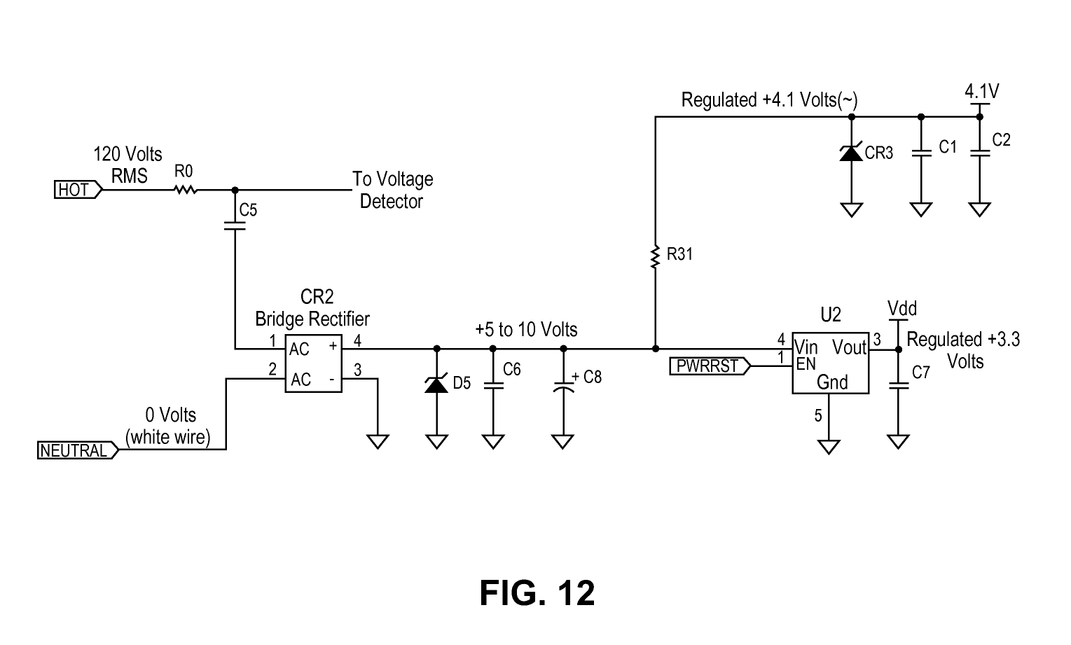

FIG. 12 illustrates an example of a power supply arrangement in the SMA for monitoring electricity usage. The power supply for the SMA is for powering small DC devices off of a regular line power. SMAs used for power monitoring will see a line voltage of 120 Volts RMS in countries like the US and typically 230 Volts RMS in rest of the countries like the UK and India, across inputs labeled HOT (also known as PHASE) and NEUTRAL. HOT may be wires in standard household Romex colored black or red in the US. NEUTRAL may be the wires colored white in the US. The white wire is also connected to ground (green or bare wire) out at the breaker box in the US.

Another aspect of this invention is that SMA+RT system may take about +3.3 Volts at up to about 150 milliAmps for the SMAs to function. Utility providers provide power typically at 120 Volts RMS AC at about 20 Amps at 60 Hz frequency in the US. A device may need to cut down the voltage and limit the current. As such, one approach would be a resistive divider network, which may generate roughly 10W in form of heat and waste of energy.

An embodiment of invention is to use a capacitor as a moderate resistor, but without burning off any current. The value of 2.7 microFarads for C5 works well to deliver about 150 milliAmps into about a 150 Ohm load. A resistor R50 in the range of 100 Ohm and 0.5 Watt may limit the current to the capacitor and the subsequent capacitors in the circuit. The AC signal is rectified with a small bridge rectifier. Circuits may be rectified with only a single diode, which may result in a voltage from the positive crest of the waveform. Moreover, bridges may deliver about 150% more power. Bridge CR2 is rated at about 1 Amp, but can take surges to about 20 Amps. After rectification, D5, a 10 Volt MOV (metal oxide varistor) may be used to protect the remaining circuitry.

In FIG. 12, C6 and C8 integrate a rectified signal and prepare a waveform for a regulator U2. C6 is a 0.1 microFarad ceramic capacitor to suppress high-frequency spurious noise either generated by the microcontroller or the regulator itself. C8 is a bulk capacitor, either of electrolytic or Tantalum construction. 100 microFarads may be a nominal value.

A regulator chosen U2 is a small-footprint, low-dropout linear regulator, with a Voltage Enable pin that, when grounded, may crowbar a voltage on the output. This feature is useful in case the microcontroller (a MOS device) experiences a parasitic latch-up (which can happen to any metal-oxide semiconductors or MOS devices encountering voltage surges, as in a lightning strike.) Instead of a RESET button just trying to reset a processor, a Voltage Enable pin would suppress all power going to the processor and enable a power cycle and the latch-up condition to discontinue. Capacitor C7 on the output of the regulator is another bulk capacitor. Spurious noise on the output of the regulator is controlled by all of the 0.1 microFarad capacitors located around the microcontroller. The circuit that contains R31, CR3, C1 and C2 is a small 4.1 Volt supply to power the phototransistor in the lighting socket and is Zener controlled and may deliver 1 milliAmp.

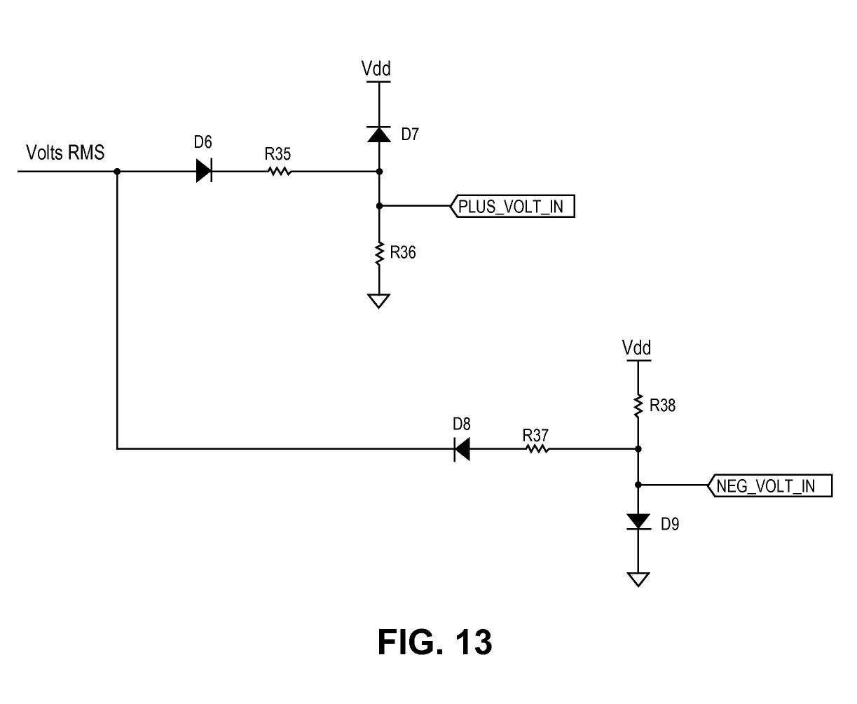

FIG. 13 illustrates one example of a voltage Detector for an SMA used for monitoring electricity usage. The voltage detector (on the hot side of the Triac (or relay), if there is one) measures an incoming or line voltage supplied to the socket. When this voltage is sampled (e.g., at 128 samples per half wave) and multiplied with the samples from the current detector, it is possible to measure power. Additionally, peaks of the voltage and current detectors should happen on the same sample, with a resistive load. If a peak of the voltage detector leads (in phase angle) the current, monitoring an inductive load (such as a motor) would suffice with a correction to the power reading which is called a power factor. In order to avoid having to supply a mid-point reference for the AC waveform to the A2D, the AC form is rectified and only half-waves are measured. In addition, 6 dB may be gained in sensitivity from the microcontroller A2D since there may not be a need to measure the entire waveform. Another circuit will detect the AC zero crossings and indicate the phase of the AC waveform, so the A2D circuit may be simplified by measuring the half-waves with respect to ground or Vdd.

Moreover, an alternative circuit may be added to obtain the voltage for the A2D. The circuit illustrated in FIG. 13 is a single-diode half-wave rectifier. D6 rectifies a positive-half of the AC waveform, and resistive divider R35/R36 brings a peak of for instance a 120 Volt RMS signal (160 Volts peak) to about 2.9 Volts for the A2D which would leave some overhead to measure higher-than-normal line voltages, should they occur. A half-wave rectifier may be used for many reasons. One reason is if a full-wave circuit (or a bridge) is used, because a power supply is referenced to a neutral phase, and because it is 90 degrees out-of-phase with respect to the line voltage, it may not be possible to reliably obtain a true value for the negative phase. The voltage would find a path through the ground of the power supply back to the Neutral lead. It is only possible to measure the positive crest of the AC signal.

Also, it is valuable to measure BOTH crests (positive and negative) of AC signal especially after a Triac (or relay) switch. Triacs (or relay) have a habit of failing short or open on only one phase, and this may have an effect on the load, if the Triac (or relay) was not totally resistive. The circuit used for the positive half-wave rectifier is duplicated by reversing the polarity of a diode, and connecting a divider to a Vdd rail. This results in a negative half-wave rectifier. For positive half-waves, the A2D will read from ground to Vdd (or thereabouts) and negative half-cycles will be negative going from Vdd to ground. An output of the A2D is a number that can be complimented, if necessary.

Next, for SMAs used for monitoring water and gas usage as an output of a flow meter, an off -the-shelf battery or combination of batteries capable of providing up to 9V and up to 500 mA may suffice. Back-up onboard battery or set of batteries may also be used for providing DC power supply to the SMA circuit for SMAs used for monitoring power usage in case the utility power supply is lost. Back-up battery power may be required in case of power outages to prevent loss of historical data stored in the SMA. An aspect of the invention is minimizing the amount of power consumed by the SMA+RT system in the process of measurement and transmission of utility data. Also, to optimize power usage for functionality of the SMA, the SMA+RT system has been designed such that SMAs are not broadcasting usage information unless and until pinged by the regulation software RT. This aspect of the invention increases battery life of the SMAs in applications where utility line power is not available for the SMAs to use.

### Regulation Technique (RT)

Unlike static or standalone energy meters in the market today like the Kill-A-Watt® monitor that has a display on the plug-in unit, one aspect of the invention has a regulation technique that collects, process and displays utility consumption data from an SMA or various SMAs, all on one computer screen. Alternatively, multiple computer screens may be utilized. The regulation technique is preferably a software program, software application, an algorithm or a combination of software/hardware application.

Another aspect of the invention is that the RT may be used for initializing or assigning a user-defined unique identifier (ID) or name which may be different from a unique MAC ID generated by the microcontroller in each SMA. The ID/names assigned by the RT would help a user easily identify appliances associated with specific SMAs. In an enterprise, a facilities manager may use this feature to assign each of the enterprise utility consuming device or assets which would further help the facilities manager compare utility usage and hence determine productivity of every asset. Alternatively, the ID/name may be defined by another device or machine.

Another aspect of the invention is the ability of the RT to have a two-way communication with every SMA. The communication from every SMA to RT would help carry the utility usage data to the RT whereas the opposite direction from RT to SMA would be used for sending regulatory signals from the RT to the microcontroller inside an SMA. The two-way communication makes this aspect of the invention not just a utility auditing tool but a tool that could be used by the user to bring about change in utility usage pattern especially to streamline usage to eliminate redundancy and waste. The two way communication feature may make this aspect of the invention a closed loop system. A benefit with a closed loop system can be illustrated by a simple example. In a scenario where an electric connection to a incandescent light bulb goes through an SMA, the RT would receive power usage data for the bulb over a wired network (power line, telephone or ethernet). If the SMA is equipped with a Triac and a photo sensor, the microcontroller inside the SMA could be programmed via the RT to operate the Triac to achieve a desired light intensity with a bulb and its surrounding. The RT could also send commands to the SMA to switch OFF power supply to the bulb based on a condition which could be a preset time.

Another aspect of the invention is the ability of the RT to present historical utility usage summary to the user. The summary screen could be common for various utilities such as power, water, gas or other utility all in one screen or a divided screen. Another aspect of the RT is to document and set baseline for usage pattern(s) and send a notification to the user when usage exceeds baseline. This feature can be best described with an example of water usage summary and notification for a user. The RT would monitor monthly usage and build a personalized usage pattern summary as data is collected monthly and eventually yearly. The RT would allow the user to set trigger(s) for notifications such as utility usage exceeded in the month as compared to the previous month or the same month in the previous year or in any other manner. The ability to configure RT would be especially useful for a facilities manager in an enterprise. The RT would allow the facilities manager to generate customized screens such as but not limited to—compare utility usage by various machine, set upper and lower control limits to apply statistical process control to maintain utility usage within limits and use standard statistical methods to catch out-of-control trends. The combination of two way communication, visibility and comparison with historical usage data could help users take proactive steps to eliminate failure of an appliance based on data and reduce waste—both resulting in cost savings.

Another aspect of the invention is the ability of the RT to receive signals from the utility provider via a smart meter to inform the user to reduce load when the utility provider faces shortages and needs users to reduce consumption to avoid brown-outs in case of power. The RT is designed to react to reduce-consumption signals from utility provider by shutting OFF or reducing consumption to user-defined limits for select user-defined appliances via their respective SMAs.

Another aspect of the invention is that the RT allows the user to use an SMA as an automatic timer. Just like the lights in a yard are turned ON and OFF at user-defined times every day, the user would have access to every SMA to set time and/or event-based limits. The feature to turn appliances ON or OFF via a remote program could be used in stores and shops to highlight different spots or aisles on different days or make it an event-based theme. For chain stores that would like to apply a common theme in all stores, this aspect of the invention offers the head quarters the ability to do so.

Generally, the RT may run on an ordinary household personal computer (PC or MAC running a PC-type OS). A standalone PC may be located in a closet or other non-conspicuous location in a residence or any other device. The computer may be dedicated for this application and not be used, in certain instances, by any residence for other purposes. The computer needs only an Ethernet connector or be connected to a communication network such as telephone or PLC.

In operation, as RT is started, the RT is programmed to identify all or one of the SMAs in its network. First-time set-up would allow the user to assign a name and location to each SMA and specify these IDs or names in a menu provided in the RT.

Further, another aspect of this invention is that the monitoring devices in form of SMAs are being polled by the regulation technique used for data collection at regular intervals. This is unlike most wireless monitoring devices that are generally programmed to broadcast a data packet and that have a receiver which has a built-in software that picks up data at certain frequencies. A difference between the two methods is that in case of RT polling SMAs, the RT decides the frequency of polling. The user would change one variable in RT as against the opposite method of monitoring devices broadcasting at set frequency where the receiver is ready to receive and the user will have to reprogram each monitoring device individually to reduce the frequency of broadcast.

Following description shown is one way of implementing a SMA polling scheme in the RT. The polling scheme in RT may follow a simple Round-robin (RR) scheduling algorithm. A RR algorithm assigns time slices to each process in equal portions and in circular order while handling all processes without priority. A RR algorithm has a separate queue for every data packet and identifies every data packet by its identifier (RR-ID). With two-way communication capability, the RT would poll or send a query to an SMA using the SMA's ID as the SMA address. Then, the algorithm would allow data to flow to take turns in transferring packets on a shared channel in a periodically repeated order. An advantage with data communication using RR algorithm is that collisions of data packets are eliminated, and a data channel bandwidth can be fully utilized without idle time especially if a monitoring system has multiple SMAs to poll. Such a streamlined data-collection process would result in minimal noise on the wired networks used for carrying utility data.

As an example, a RT initial set-up description using a system used for monitoring electricity usage in a home is described. There may be several set-up screens on the application to “set-up” a management scheme needed for a particular residence. This would give the RT application an idea as to how the user may want to manage their utility information. Outlets that cannot be switched on or off may be noted and certain appliances may also be noted. Lights could be programmed for their output. When a room is darkened, the lights would come on automatically. This feature can be extended to what can be termed as an event/mood/theme based lighting. The RT will allow the user to have certain programs which when instantiated could turn, for instance, the living room lighting into a “movie setting” whereby lights around the TV will be dimmed and optimized for watching a movie. In another instance, certain portions (collections/ art pieces/paintings) could be highlighted by using a “social gathering” light setting. Although these examples focus on lighting, the RT could be applied to produce any user defined setting for appliances that run on electric current which could be also be based on interaction with environmental sensors like lights, audio, temperature control, motion sensors, etc.

Another aspect of the invention applies to LED lighting. There are 3 basic types of LEDs—Red, Green and Blue. When these basic colors are mixed in different combinations & quantities, one can achieve every possible color and shade in the visible light spectrum from dark (lights off) to white light (mix of all colors). Current can be supplied to specific locations and number of LEDs to emit a specific color using the RT. The RT application will display a color palette on the PC for the user to pick a color from and an algorithm may determine location and quantity of LEDs in a LED array to be turned on to achieve the desired output. This feature can be used by the user to shine LED light on walls, in a corner of a room or on art pieces to create special effects with a click of a button. Architects and interior decorators can use this feature of invention to offer customers the ability to create ambience in their homes/offices/ stores that can be changed daily/seasonally/occasionally without a need to paint the wall or structure. In addition, since LEDs are extremely sensitive to voltage and current variations and essentially require current-regulated power supplies, the SMA+RT system will be able to serve this function and help extend the life of the LEDs.

Another aspect of the invention applies to a SMA feature to override a command (or a disabling feature) sent by the RT. For lights that are switched by a switch by a door in a home or enterprise, the RT would perform much like a request-for-light flag. For example, the RT could be programmed for a “power saving mode” to send a signal to all lights controlled by SMAs to turn off after midnight until 7 AM. If the user left one or several light switches in the “ON” position, RT would shut off all user-defined lights at the SMA-level but the switches may remain in the ON position. If a user would like to turn some lights back on, the RT would be programmed such that if the user flips a light switch OFF and then ON, the SMA would go in an override mode for a fixed duration of time and turn the light back on for that duration. If the user left the light switch ON for the preset duration stored in the RT, the RT would again turn the light back off after that duration until a separate parameter in the RT stops the RT. An ability of customizing the RT for such applications effectively overcomes the drawbacks associated with other energy management techniques that involve motion sensors and keep lights on if motion is detected. RT will allow users to define override or interrupt mode and still have the system go back to do what it is programmed to do.

Another aspect of this invention is to reduce the SMA to a size small enough for utility consuming device makers such as manufacturers of air conditioners units, washers, dryers and manufacturing equipment used in enterprises to embed an SMA in line with the power supply circuit inside the appliance to make it a “smart” appliance that can communicate with the outside world if the user has access to the RT. This would reduce set-up time down to setting up RT on a computer. By “prioritizing” appliance usage this way, this aspect of the invention would save users utility costs especially if a utility company implements time-based rates for utilities. With a programming option in the RT, users would be able to have SMA-enabled utility consuming devices perform certain tasks during non-peak hours and still get work done and not pay extra costs.

Next, RT mode of operation is described. Each SMA has a microcontroller with finite amount of memory to store data. Data may get over-written when the SMA memory gets full or depending on a setting in the microcontroller firmware. Depending on the RT algorithm, utility data in each SMA will be polled and collected at a user-defined or factory-programmed frequency. Data would be stored in a designated folder on a hard disk of the host computer in which RT operates from each data point and would be assigned a time-stamp which is the time on the host computer or time on a timer on each SMA. The RT would process the data and may display a complete breakdown of utility consumption in a user friendly graphical form such as a pie chart or bar graph. Because the utility data has a time stamp, the computer CPU would also be able to display time based comparison and usage trends. This data would be processed and could be published on the internet in which case it would be accessible remotely. The processed or raw data can also be ported over to the utility company, a demand response or a data processing firm via a smart meter, smart grid or via a special access to a website where data is sent real time or at user-defined intervals via the internet.

Another aspect of the invention is that, a SSL protocol (Secure Socket Layer) can be deployed on the host computer, or a remote client that is accessing server information via the internet to ensure user privacy and data security in the transaction. The host computer would store utility usage information from the SMA in an appropriate format that can be presented through a GUI or retrieved via internet. Mobile devices such as I-phone, Blackberry, etc with internet connectivity could be used to retrieve and display the processed data.

Another aspect of this invention would be to utilize a technology called PLC (Power Line Communications) which is also known as BPL (Broadband over Power Lines) to communicate to a host server. The advantage of the BPL technology is that existing power lines are used for data communication. This aspect of the invention uses the BPL as a wired communication network to communicate utility usage data to and from all SMAs which would be connected to a common network to a RT host computer. The RT host computer would also be connected to the electric network. The BPL topology typically allows transmission of 128K bits per second which is sufficient for implementing a polling method for data collection without disrupting a function of the electric network (i.e. to conduct electricity to utility consuming devices). An added advantage of this aspect of the invention using BPL technology is that the same electric network would be used for data communication that could power the SMAs and the host computer.

FIG. 6 illustrates a SMA+RT system that uses the BPL mode of communication. The data collector/convertor unit 220 serves as a gateway for data polled from every SMA 215 through to the host computer 230 via wired or wireless ethernet 225. Each SMA has a communication functional block that has BPL circuitry that would send utility usage data over the phase 205 and neutral 210 components of the power line.

In FIG. 6, element 235 illustrates a communication functional block inside the SMA. Communication block 235 comprises of basic circuitry such as clock 250, a reset circuit 245 and a power supply 235. The functional block interfaces with a microcontroller 265 via a standard interface such as a Serial Peripheral Interface (SPI) bus and a flash memory for utility usage data accumulation/storage until the SMA is polled by the RT. A component of this functional block is the PLC chipset 260. The chipset will have related circuitry 255 for analog front end (AFE) that processes AC signals to digital signals or vice versa. An output of the AFE circuit 255 goes to the AC outlet 271 which then carries signals on the power line to the gateway card 220. Having onboard memory would allow polling frequency from the RT to be set such that data may or may not be uploaded to the host computer in real-time or when the SMA+RT system finds a vacant time slot for bulk upload.

In FIG. 6, element 275 illustrates circuit details on a gateway card 220. Gateway card 220 assimilates utility usage data sent on power lines by SMAs in the circuit and converts the assimilated data to a data format that can be ported to the RT host computer via a wired or wireless ethernet connection. In short, gateway card 220 serves as a gateway for all the SMA data into the host computer. The PLC interface card has the standard circuit elements present in a circuit such as clock 280, reset 285, regulator(s) 281 and power supply 288. Two components on this card are the PLC AFE 286 and a microcontroller 287 for generating signals that can be communicated via the ethernet port 290 to the host computer 273. The RT could monitor data for a single SMA or a group of SMAs and get a report in a user defined format of a SMA ID, and of utility parameters such as voltage, current, power, peak Power or electricity and also of flow rate or pressure for water or gas.

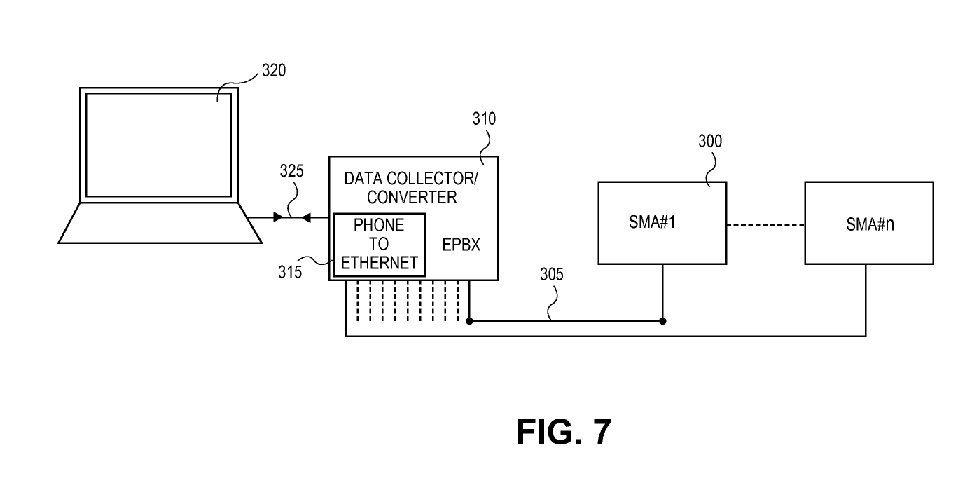

FIG. 7 illustrates setup for data communication over a telephone line. Each SMA 300 may have an individual telephone line going to a data collector/convertor unit 310, which for phone lines may be a standard electronic private branch exchange (EPBX) system. Such a network where all data lines terminate into a collector at a center may be called a “star configuration”. The EPBX system is a phone system that can run on ordinary computers, allowing telephones to work just like any other computer application. Conventional phone systems run on proprietary, special purpose computers only. A telephone gateway card 315 serves as an interface for routing data from the EPBX system to the host computer 320 via wired or wireless ethernet connection 325. The telephone gateway card 315 may be located remotely and not on or as part of the EPBX system.

A data communication system over ethernet would work the same way as a system with telephone lines as described in above paragraphs. A difference may be that instead of a EPBX system, an off-the-shelf Ethernet hub or a network hub may be used.

Next, SMA recognition techniques are described below. The BPL circuitry will, upon power-up or reset (as in a power outage), perform and auto-discover like BPL devices and ones that are registered in the RT. An alternative method would be that the BPL technology utilizes a Data Encryption Standard (DES encryption) to select a key code that will identify SMAs with the same key code installed in the electric network that the RT has access to. Once all of the pertinent SMAs have been identified, the host computer would keep a list of all identified SMAs internally and would poll as well as communicate with the corresponding SMAs.

As opposed to the standard Internet Protocol version 4 (IPv4) protocol used on many BPL networks, this aspect of the invention operates half-duplex at a time. The standard IPv4 is based on a full duplex protocol for a two-way communication between two connected devices at the same time. A half-duplex, on the other hand, is based on one-way communication at a given instance where the one-way communication could be in either direction such as from a SMA to RT or from RT to a SMA. This will keep the probability of data collisions or interference down as multiple circuits will not transmit at will. The RT would poll individual SMAs and data will be sent back to the host computer by request.

In the event the host server may not offload data from an individual circuit, each circuit will need to buffer up its data for as long as necessary. Utilizing 32-bit variables internally will allow data buffering into time frame of years, which will be sufficient. If an individual circuit does not respond to a data request, the host server will retry to establish connection either by acknowledgement or discovery of all circuits on the network. If communications to that circuit continues to fail, the host server will generate an error for the user.

Each SMA may have an embedded 6 bytes Media Access Control (MAC) address or an identifier (ID) that uniquely identifies itself. MAC addresses may be assigned by a manufacturer of network ICs in a memory chip, or by some other firmware mechanism. If assigned by the manufacturer, a MAC address usually encodes the manufacturer's registered identification number. The MAC address may also be known as an Ethernet hardware address (EHA), hardware address, adapter address, or physical address. MAC addresses may be formed according to rules of one of three numbering name spaces managed by the IEEE: MAC-48, EUI-48, and EUI-64. All SMAs are on a same VLAN or private network (subnet) which makes the system very secure.

The software implementation on the SMA has 3 layers. An embedded application or upper layers interfaces directly with a data link layer which is responsible for initializing devices on board, broadcasting its MAC address, updating the RT on the host computer periodically with ID data or other data. Protection from eavesdropping can be provided by employing an encryption scheme such as AES. A layer 2, data link layer would consist of device drivers which are responsible for controlling hardware as well as transmitting and receiving data. A layer 1 or PHY layer represents the hardware implementation of IEEE 802.3 standards for wired LAN in silicon.

Another aspect of this invention is a feature that Ethernet networks can support and that is Power over Ethernet. This is a feature for systems that need to be monitored which are not close to a source of electric power. Ethernet running on Cat 5 wire comprises four sets of twisted pair of wires. One set of twisted pair is for transmit and the other is for receive. This leaves two sets that are not used. These unused pairs are grounded. Also note that transmit and receive lines in Cat 5 wire are transformers coupled on both ends to terminate the twisted pair (which is a transmission line) and to decouple any 60 Hertz noise from house AC wiring. The IEEE spec. 802.3a-f allows for a 48 Volt battery (DC supply) to be connected on the switch end of the Ethernet connection. It provides for up to 35 Watts to be delivered to a remote device. The Ethernet cable drops about 2 Watts per 100 meters. The SMA+RT monitoring circuit uses about ½ Watt, or other wattage levels configured to provide sufficient amount of power for powering other devices. Additional power to be used for relays, solenoids, small motors is left.

Further, data packets broadcasted by each of the SMAs in a network will be distributed over the power lines and received by a receiver which then reformats utility information, if necessary, before routing to a data storage device. Such a storage device may always be ON for SMA data to be stored without interruption. In an event that the data storage device is powered OFF, the SMAs will be able to hold a limited amount of data depending on the granularity of data collection and the amount of memory available in the SMA. For instance, if a SMA is able to hold 15 minutes worth of data produced, data may be overwritten every 15 minutes.

The advantage of storing SMA data on site and not port it via internet to the host computer is to allow the user to be in control of the data. The RT would reside on the host computer or a remote server for ease of upgrade and maintenance. The user would login to RT remotely or locally and would be given an option to view current or historical utility usage profile. One way to enable a secure remote access is for the user to provide the IP (Internet protocol) address or set-top box ID of the network on which usage data is stored. Each time the user logs-in, the RT would match the IP address of the user's computer or set-top box ID for identification before providing access. The data storage device could be a PC, a media hub or any “box” that has non-volatile memory in it. The data storage device may be a household PC, a server, a set-top box, even a modem or router retrofitted with sufficient memory or any device such as next-generation TVs that might have built-in memory.

There are various options for providing processed data generated by the RT. Such data could be provided to the utility via a smart meter or via the broadband or Cable service provider with user's consent. The RT application may even serve as a portal for a user agreement from where the utility data could be shared with utility company or any government or private entities interested in such data.

### SMA+RT Applications

SMA+RT systems and methods may be applicable to townships and residential Applications. For example, power usage monitoring, optimization, control for utility consuming devices/equipment for single or multiple residential units, club houses, apartments and townships may be provided. The applications may be useful for monitoring and regulation of all types of residential appliances such as washers, refrigerators, microwaves, lighting, HVAC. The applications may be useful for monitoring and regulation of office equipment such as computers, printers, FAX machines, servers, chargers, TVs, VCRs, recording devices, security systems. Further, the applications may be useful for monitoring and regulation of outdoor appliances such as pools spas, pumps, Solar PV installations, chargers for hybrid vehicles and other such systems.

SMA+RT systems and methods may be applicable to commercial applications. For example, power usage monitoring, optimization, control for utility consuming devices such as machinery and equipment used in commercial enterprises at one or multiple locations may be provided. The applications may be useful for monitoring and regulation of all types of commercial appliances such as vending machines, lighting, HVAC. The applications may be useful for monitoring and regulation of office equipment such as computers, printers, FAX machines, servers, chargers, TVs, VCRs, recording devices, security systems, individual servers, switch boxes, storage devices in a server rack. The applications may be useful for monitoring and regulation of outdoor appliances such as pools spas, pumps, compressors, Solar PV installations, chargers for hybrid vehicles and other such systems. Further, the applications may be useful for monitoring usage of power by every appliance (server, storage device and switch box) in a server rack in a data center.

Yet, another aspect of the invention is use of a power consumption profile of every component in a server rack in coordination with virtualization software used for improving Power Usage Effectiveness (PUE) and optimizing power usage in data centers. By tracking power usage at every server, a data center manager may be able to distribute high power consuming servers in different racks in the data center. By distributing high-power consuming servers in multiple racks, it may be possible to reduce or eliminate a phenomenon called “hot-spot” inside the data center. A hot-spot is generated in a data center when multiple servers in the same rack consume power at the same time and emit more heat as compared to servers in surrounding racks that may be idle or may be consuming less power and hence may be cooler. Such temperature differences amongst racks and the resulting hot-spots generally may require lower temperature setting for cooling the data centers.

Also, another aspect of the invention is to maintain a uniform temperature profile from rack to rack inside a data center by an even distribution of generally high power consuming servers based on power usage profile collected by SMA coupled with every server in a data center. Some percentage of power consumed by a server is converted in form of heat. The more the power consumed, the more the amount of heat generated and higher the temperature of⁻the server. By lowering an overall temperature distribution and reducing occurrence and/or severity of hot spots, a data center manager could increase the temperature setting required to keep the data center cool. Increased temperature setting in a data center results in lowering of cooling costs.

Yet further, another aspect of the invention is use of in-built single or multiple sensors to monitor critical process parameters such as temperature, humidity, pressure sensors in every SMA connected to each server to collect real-time process parameter data at plug-in socket of each component in a rack. By monitoring a combination of process parameters and power usage at every appliance in a rack, the RT can be configured to provide a user a complete distribution of not only power usage but also map a profile of every critical parameter across the data center at each appliance-level. The RT could be further configured to suggest set-up changes to the user to balance the distribution of power usage and process parameter variation across the data center. Once the changes are implemented, the SMA+RT system could remap the data center and suggest further fine tuning until the distribution is within acceptable limits.

As a result of balancing power usage distribution which in turn influences temperature, humidity and pressure distribution in the data center, the user may be able to increase the temperature setting in the data center without the risk of creating hot spots and preventing server tripping events. Alternatively, a similar approach could be taken to improve uptime and reduce operating costs using the SMA+RT system at various enterprises such as chemical plants, industrial freezers and cold storage for spirits and food industries.

Moreover, the SMA+RT system and method may be applicable to Industrial Applications. For example, monitoring power usage, optimization, control of equipment, machinery, and appliances used in manufacturing processes, industrial plants and factories at machine, plant and enterprise level may be provided. The applications may be useful for monitoring and regulation of appliances such as compressors, pumps, generators, drives and CHP. The applications may be useful for monitoring and regulation of heavy machinery such as rolling mills, vibratory, reciprocating and rotating machinery.

Next, SMA+RT systems and methods may also be used to monitor water or gas usage by interfacing with flow meters and remote regulation by interfacing with a solenoid valve on the same line. Another aspect of this invention is enabling prepaid water or gas metering service for a township office by monitoring and displaying real time and periodic information such as daily, monthly, yearly water or gas usage for every consumer and interfacing usage with an off-the-shelf billing software. Another aspect of the invention is displaying usage report of all utilities such as water, power and gas on one screen and providing a secure access to the data to the consumer, utility provider, demand response firms, city municipality and government body. In such a system, the RT could be optimized to notify the consumer via communication means such as email, tweet or SMS of important account related activities such as excess usage as compared to historical usage pattern or a need to recharge account.

Additionally, security and fire alarms could be driven and monitored with a power over Ethernet (POE) concept. Security alarm sensors would be powered with the POE switch source, and data would be routed back to the monitoring application. These would include security devices such as motion sensors, cameras, heat detectors, smoke detectors and IR detectors. Since such security devices would communicate with a host computer via a SMA+RT system, it may be possible to monitor the status of security devices and alert the user in case a device failed to communicate.

Another application is that SMA+RT system could be used to transmit music and voice as in an intercom throughout a house or business. A COBRA-net standard could be used wherever Ethernet is used. Remote speakers could be powered with 35 Watts (or other wattage) available through the Ethernet cable (5-10 Watts is sufficient for most applications) and microphones could be placed along with the speakers to monitor voice remotely.

Lastly, the SMA+RT system may be used in combination with advanced sensory technology such as Smart Dust—a technology that consists of micro-sensors that are used for sensing environmental conditions such as temperature, light, pressure, etc. A system using Smart Dust technology in coordination with a SMA+RT system would involve use of millimeter sizes sensors (smart “dust”) and communication packages that can spread over an area and could further sense and communicate temperature, light, humidity, pressure, etc via RF, laser or by other means to a receiver. Sensors may be placed within a house or enterprise for monitoring environmental data and transmitted over the SMA+RT system communication channel.

While preferred embodiments of the present invention have been shown and described herein, it will be obvious to those skilled in the art that such embodiments are provided by way of example only. Numerous variations, changes, and substitutions will now occur to those skilled in the art without departing from the invention. It should be understood that various alternatives to the embodiments of the invention described herein may be employed in practicing the invention. It is intended that the following claims define the scope of the invention and that methods and structures within the scope of these claims and their equivalents be covered thereby.

We claim:

1. A system for optimizing utility usage comprising:
a monitoring device adapted to be connected to a utility point and a utility consuming device;
the monitoring device configured to monitor and regulate utility usage information of the utility consuming device and further configured to assign a unique identifier to the monitoring device;
the monitoring device comprising a measurement circuit for measuring utility usage information, wherein the measurement circuit is coupled to the utility point; and
a central processing unit (CPU), the monitoring device being further configured to communicate with the CPU through a communication network, wherein the monitoring device is configured to transmit utility usage information of the utility consuming device to the CPU on the unique identifier and wherein the monitoring device is configured to receive utility usage information of the utility consuming device and wherein the CPU is configured to process the utility usage information based on the unique identifier.

2. The system of claim 1, wherein the utility point is a power point.

3. The system of claim 1, wherein the utility point is a flow meter.

4. The system of claim 1, wherein the utility usage information is selected from a group consisting of power usage information, water usage information, gas usage information and sewage usage information.

5. The system of claim 1, wherein the utility consuming device is selected from a group consisting of power consuming device, water consuming device, gas consuming device and sewage device.

6. The system of claim 1, wherein the CPU comprises an application for managing utility usage information sequentially based on the unique identifier.

7. The system of claim 1, further comprising a sensor coupled to the monitoring device configured to sense a surrounding condition of the utility consuming device.

8. The system of claim 1, wherein the monitoring device is a semiconductor integrated circuit.

9. The system of claim 1, wherein the monitoring device comprises a microcontroller for processing utility usage information of the utility consuming device.

10. The system of claim 10, wherein the monitoring device comprises a communication circuit coupled to the microcontroller for communicating with the CPU and wherein the microcontroller is configured to communicate with the communication circuit over a wired communication line.

11. The system of claim 10, wherein the monitoring device comprises a regulation circuit coupled to the microcontroller for regulating the utility usage information.

12. The system of claim 1, wherein the monitoring device has a size no greater than the utility point.

13. The system of claim 1, wherein the monitoring device has a length no greater than 4.5 inches.

14. The system of claim 1, wherein the monitoring device has a width no greater than 2.75 inches.

15. The system of claim 1, wherein the unique identifier is a media access control (MAC) address.

16. A method for optimizing utility usage comprising:
providing a monitoring device at a utility point;
coupling an utility consuming device to the monitoring device, assigning a unique identifier to the monitoring device;
measuring utility usage information of the utility consuming device with the monitoring device;
transmitting utility usage information from the monitoring device to a central processing unit (CPU) using the unique identifier; and
processing the utility usage information at the CPU to regulate utility usage of the utility consuming device.

17. The method of claim 16, further comprising sending utility regulation information from a user to the CPU.

18. The method of claim 16, further comprising priority sequencing of the utility consuming device in comparison to another utility consuming device based on the utility usage information.

19. The method of claim 16, wherein the measuring step comprises measuring an amount of current being used by the utility consuming device.

20. The method of claim 16, wherein the measuring step comprises measuring voltage of the utility consuming device.

21. The method of claim 16, wherein the measuring step comprises measuring a pulse or digital counter from the utility consuming device.

22. The method of claim 16, further comprising providing real-time or near real-time updates of utility usage to a user.

23. The method of claim 16, further comprising:
polling the monitoring device using the unique identifier sequentially;
upon polling of the monitoring device, transmitting utility usage information of the utility consuming device sequentially from the monitoring device to the CPU.

24. The method of claim 23, further comprising:
providing more than one monitoring device at more than one utility point;
assigning a unique identifier to each of the monitoring devices;
upon polling of more than one monitoring device, aggregating utility usage information from each of the polled monitoring devices sequentially based on each of the unique identifiers at the monitoring device; and
upon polling of more than one monitoring device, transmitting utility usage information from each of the monitoring devices sequentially based on each of the unique identifiers.

25. The method of claim 16, further comprising displaying utility usage information to a user based on the unique identifier.

26. The method of claim 16, wherein the unique identifier is a media access control (MAC) address.
